(19) United States
(12) Patent Application Publication
(10) Pub. No.: US 2008/0220197 A1
(43) Pub. Date: Sep. 11, 2008

(54) PHASE-CHANGE RECORDING FILM WITH STABLE CRYSTALLIZATION RATE, TARGET AND PROCESS FOR PRODUCING THE PHASE-CHANGE RECORDING FILM

(75) Inventors: Jonq-Ren LEE, Tainan (TW); Tsung-Eong HSIEH, Hsinchu (TW); Yuan-Chang LAI, Tainan (TW); Hung-Chuan MAI, Hsinchu (TW)

Correspondence Address: PATENTTM.US, P. O. BOX 82788, PORTLAND, OR, 97282-0788, US

(73) Assignee: SOLAR APPLIED MATERIAL TECHNOLOGY CORP., Tainan (TW)

(21) Appl. No.: 12/041,187

(22) Filed: Mar. 3, 2008

(30) Foreign Application Priority Data
Mar. 5, 2007 (TW) 096107492

(51) Int. Cl. B32B 1/00; C23C 14/34

(52) U.S. Cl. 428/64.5; 204/192.11

(57) ABSTRACT

A phase-change recording film with stable crystallization rate and a composite target for producing the film are composed of 10 to 50 atomic percent of phase-change material containing Te or Sb and 50 to 90 atomic percent of dielectric material. Another target for producing the film is composed of dielectric material and a phase-change material containing Te or Sb attached to the dielectric material. A co-sputtering process for producing the film uses a target made of dielectric material and a target made of phase-change material containing Te or Sb to co-sputter. Because the crystallization rate of the phase-change recording film does not change as the thickness of phase-change recording film varies, manufacturing the phase-change recording film does not require to be precisely controlled unduly.

### BACKGROUND OF THE INVENTION

1. Field of Invention

The present invention relates to a phase-change recording film, and more particularly to a phase-change recording film with stable crystallization rate that does not change as the phase-change recording film thickness varies.

2. Description of the Related Art

A conventional phase-change disc or recording medium comprises a first dielectric film, a phase-change recording film, a second dielectric film and a metal film that are plated sequentially on a polycarbonate substrate with multiple grooves. Then a protective resin layer covers the metal film.

The phase-change disc uses lasers to hit the phase-change recording film and to change a phase of the phase-change recording film between crystalline phase and amorphous phase. Thus, a difference of reflectivity between crystalline phase and amorphous phase is detected to recognize digital signals. When the phase-change recording film is hit by a pulse of a high power laser, the phase-change recording film locally melts and then rapidly cools down to form an amorphous structure. Accordingly, data are written into the phase-change disc. When the phase-change recording film is hit by a pulse of a low power laser, the phase-change recording film is recrystallized locally. Accordingly, data are erased from the phase-change disc.

In order to write and erase data with low power and short pulse and allow the phase-change disc to be written and erased repeatedly, the difference of reflectivity between crystalline phase and amorphous phase of the phase-change recording film has to be significantly large. Additionally, the phase-change recording film has to be sandwiched between two dielectric films to avoid a problem of heat dissipation. Therefore, manufacturing the conventional phase-change disc requires to plate multiple films, which is complicated and takes more time.

Moreover, crystallization rate of the conventional phase-change recording film is related closely to a thickness of the phase-change recording film. With reference to FIG. 7, Yung-Sung Hsu et al. (Proceedings of SPIE Vol. 5380) published analyses about reflectivities of Sb₇₁Te₂₉ with different thicknesses of the phase-change recording film versus various temperatures. From the analyses, as the thickness of the phase-change recording film varies, a slope of each curve in FIG. 7 changes, i.e. the crystallization rate changes as the thickness of the phase-change recording film varies. Because the crystallization rate of the phase-change recording film in the phase-change disc is required to be precisely controlled, the thickness of the phase-change recording film must be precisely controlled when the phase-change recording film is plated. Therefore, manufacturing the phase-change disc has to be carefully controlled, so that manufacturing costs are raised.

To overcome the shortcomings, the present invention provides a phase-change recording film with stable crystallization rate, target and process for producing the film to mitigate or obviate the aforementioned problems.

### SUMMARY OF THE INVENTION

The primary objective of the present invention is to provide a phase-change recording film with stable crystallization rate that does not change as the phase-change recording film thickness varies. The present invention also provides targets and process for producing the phase-change recording film.

A phase-change recording film in accordance with the present invention is composed of 10 to 50 atomic percent of phase-change material containing Te or Sb and 50 to 90 atomic percent of dielectric material.

A composite target for producing the phase-change recording film in accordance with the present invention is composed of 10 to 50 atomic percent of phase-change material containing Te or Sb and 50 to 90 atomic percent of dielectric material.

A target for producing the phase-change recording film in accordance with the present invention is composed of a substrate made of a dielectric material and having a surface and at least one sheet made of a phase-change material containing Te or Sb and attached to the surface of the substrate.

A co-sputtering process for producing the phase-change recording film in accordance with the present invention uses a target made of a dielectric material and a target made of a phase-change material containing Te or Sb to co-sputter.

Because the phase-change recording film in accordance with the present invention has a stable crystallization rate, manufacturing processes of the phase-change recording film needs not to be precisely controlled unduly and manufacturing costs can be lowered.

Other objectives, advantages and novel features of the invention will become more apparent from the following detailed description when taken in conjunction with the accompanying drawings.

### BRIEF DESCRIPTION OF THE DRAWINGS

FIG. 1 is a flow diagram of a target-attached sputtering process to produce a phase-change recording film in accordance with the present invention;

FIG. 2 is a flow diagram of a co-sputtering process using two targets to produce a phase-change recording film in accordance with the present invention;

FIG. 3 is a flow diagram of a sputtering process using a composite target to produce a phase-change recording film in accordance with the present invention;

FIG. 4 is a photomicrograph of a phase-change recording film in accordance with the present invention in example 1;

FIG. 5 is a chart of reflectivity of a phase-change recording film in accordance with the present invention versus temperature under different elevated temperature conditions;

FIG. 6 is a chart of reflectivity of a phase-change recording film in accordance with the present invention versus temperature with different thicknesses of the phase-change recording film; and

FIG. 7 is a chart of reflectivity of a conventional phase-change recording film in accordance with the prior art versus temperature with different thicknesses of the phase-change recording film.

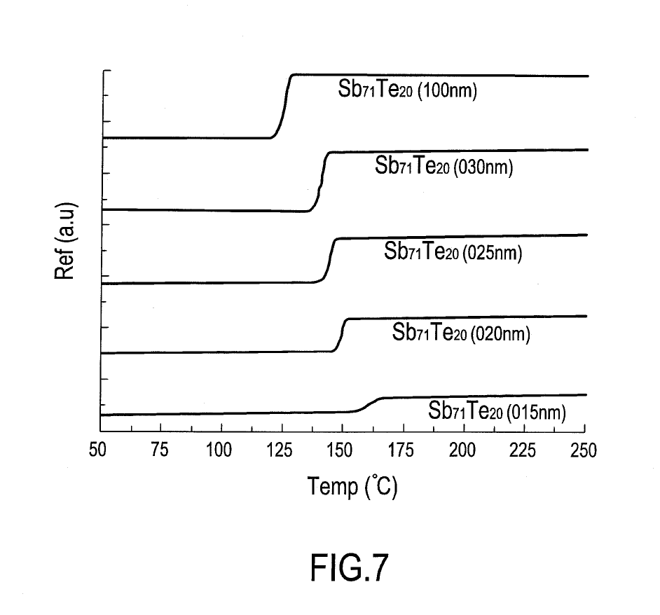

### DETAILED DESCRIPTION OF THE INVENTION

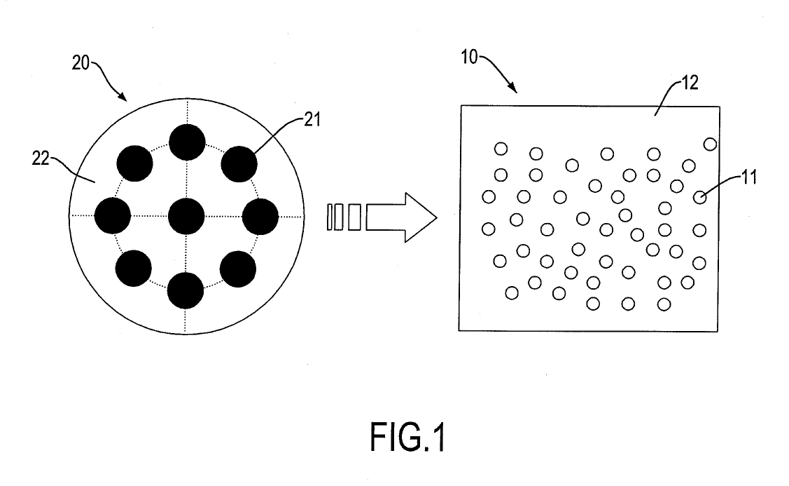

With reference to FIG. 1, a phase-change recording film (10) with stable crystallization rate in accordance with the present invention is composed of 10 to 50 atomic percent of a phase-change material (11) containing tellurium (Te) or stibium (Sb) and 50 to 90 atomic percent of a dielectric material (12). The phase-change material (11) containing Te or Sb may be GeSbTe, AgInSbTe, SbTe, GaInSbTe or GeTe. The dielectric material (12) may be Ta₂O₅, Si₃N₄, ZnS, SiO₂ or a mixture thereof.

The phase-change recording film (10) can be manufactured with a target-attached sputtering process, a co-sputtering process using two targets or a sputtering process using a composite target.

The target-attached sputtering process uses a target (20) composed of a substrate (22) made of dielectric material (12) and at least one sheet (22) made of phase-change material (11) containing Te or Sb. The substrate (22) has a surface. The at least one sheet (21) is attached to the surface of the substrate (21). Then the target (20) is sputtered and the dielectric material (12) and the phase-change material (11) are deposited on a disc such as a polycarbonate disc to form a phase-change recording film (10) with stable crystallization rate. The phase-change material (11) containing Te or Sb may be GeSbTe, AgInSbTe, SbTe, GaInSbTe or GeTe. The dielectric material (12) may be Ta₂O₅, Si₃N₄, ZnS, SiO₂ or a mixture thereof.

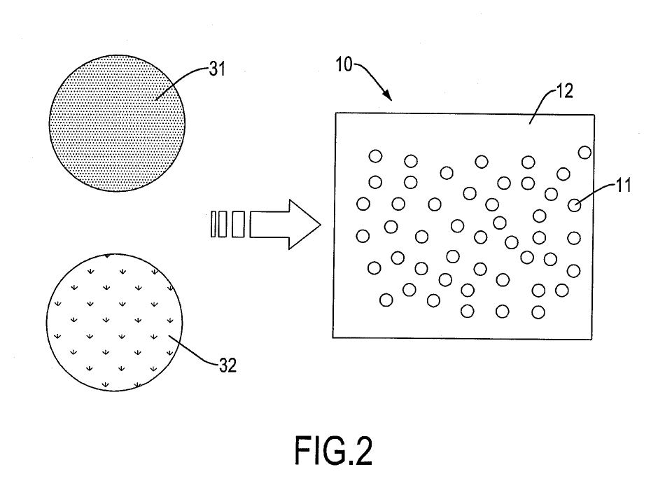

With reference to FIG. 2, the co-sputtering process uses a target (31) made of a dielectric material (12) and a target (32) made of a phase-change material (11) containing Te or Sb simultaneously. The two targets (31)(32) are co-sputtered and the dielectric material (12) and the phase-change material (11) are deposited on a disc such as a polycarbonate disc to form a phase-change recording film (10) with stable crystallization rate. The phase-change material (11) containing Te or Sb may be GeSbTe, AgInSbTe, SbTe, GaInSbTe or GeTe. The dielectric material (12) may be Ta₂O₅, Si₃N₄, ZnS, SiO₂ or a mixture thereof.

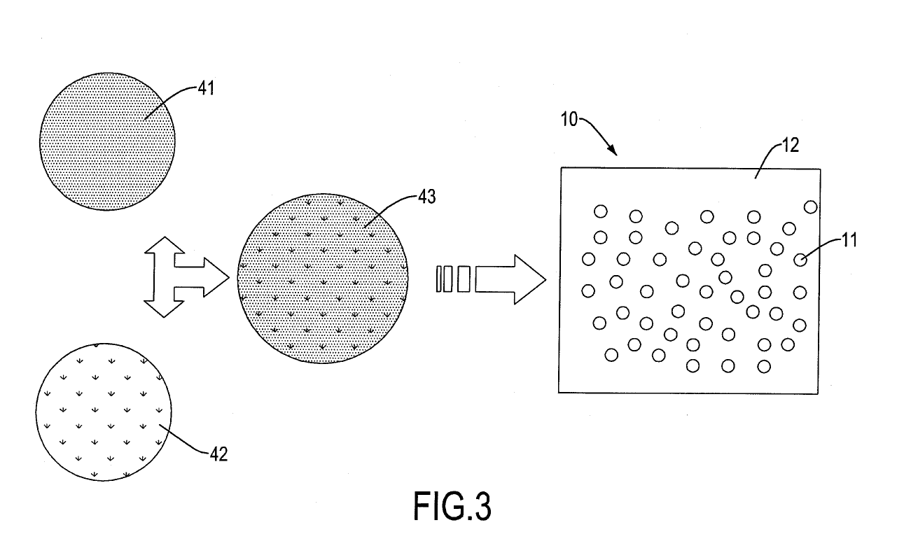

With reference to FIG. 3, the sputtering process using a composite target (43) use a substrate (42) of dielectric material (12) and a substrate (41) of phase-change material (11) containing Te or Sb to manufacture the composite target (43). The composite target (43) is composed of 10 to 50 atomic percent of phase-change material (11) containing Te or Sb and 50 to 90 atomic percent of dielectric material (12). The composite target (43) is sputtered and the dielectric material (12) and the phase-change material (11) are deposited on a disc such as a polycarbonate disc to form a phase-change recording film (10) with stable crystallization rate. The phase-change material (11) containing Te or Sb may be GeSbTe, AgInSbTe, SbTe, GaInSbTe or GeTe. The dielectric material (12) may be Ta₂O₅, Si₃N₄, ZnS, SiO₂ or a mixture thereof.

The following examples further illustrate the present invention but are not to be construed as limiting the invention as defined in the claims appended hereto.

### EXAMPLE 1

### Target-Attached Sputtering Process

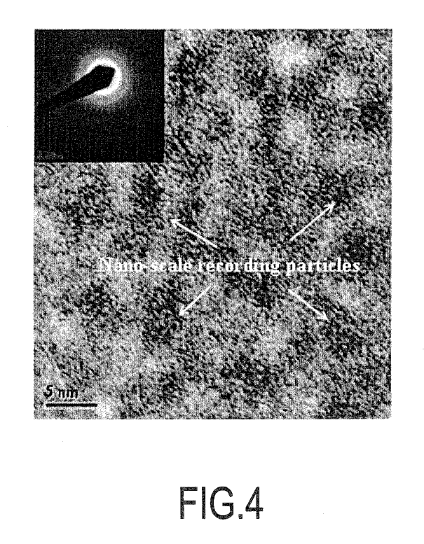

SiO₂ serves as a substrate of a target and a sheet of AgInSbTe is attached to a surface of the substrate. An area ratio of AgInSbTe to the substrate is 30 percent. The attached target is RF (radio frequency) sputtered with a sputtering power of 100 W in a sputtering gas of Ar at a flow rate of 10 sccm under a work pressure of 3 mtorr to form a phase-change recording film with various thicknesses (20, 30, 40, 50, 60, 90 and 100 nm). With reference to FIG. 4, a photomicrograph of the phase-change recording film in Example 1 shows that the phase-change material of AgInSbTe forms nano-scale recording particles that distribute evenly in the dielectric material of SiO₂.

### EXAMPLE 2

### Co-Sputtering Process Using Two Targets

A target of AgInSbTe or GeSbTe and a target of SiO₂ or ZnS—SiO₂ are RF co-sputtered simultaneously in a sputtering gas of Ar at a flow rate of 10 sccm under a work pressure of 3 mtorr to form a phase-change recording film with various thicknesses (20, 30, 40, 50, 60, 90 and 100 nm). The target of SiO₂ or ZnS—SiO₂ is sputtered with a sputtering power of 25 W to 50 W. The target of AgInSbTe or GeSbTe is sputtered with a sputtering power of 100 W to 150 W.

### EXAMPLE 3

### Sputtering Process Using Composite Target

A composite target is formed with a dielectric material such as Ta₂O₅, Si₃N₄, ZnS, SiO₂ or a mixture thereof and a phase-change material such as GeSbTe, AgInSbTe, SbTe, GaInSbTe or GeTe by powder metallurgy. The powder metallurgy is performed at a temperature of 400° C. to 1000° C. under a pressure of 4500 psi to 15000 psi. The composite target is sputtered to form a phase-change recording film.

### EXAMPLE 4

### Reflectivity at Different Temperatures

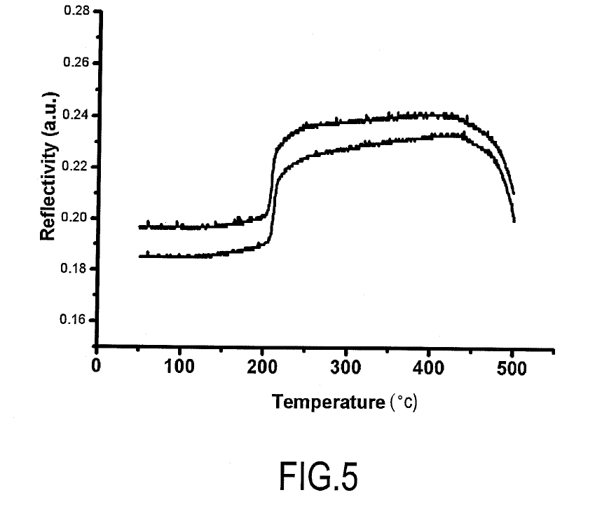

With reference to FIG. 5, reflectivities of a phase-change recording film of AgInSbTe and SiO₂ at different temperatures under two elevated temperature conditions (40° C./min and 60° C./min) are shown. The reflectivity of the phase-change recording film of AgInSbTe and SiO₂ has a significant change at about 200° C. Therefore, though the phase-change recording film in accordance with the present invention is a single-layer structure, the phase-change recording film also provides a significant difference of reflectivity and has a remarkable potential to improve the multiple-layer structure of a conventional phase-change disc. Manufacturing processes of phase-change discs is substantially simplified and saves time.

### EXAMPLE 5

### Reflectivities of Phase-Change Recording Films with Various Thicknesses

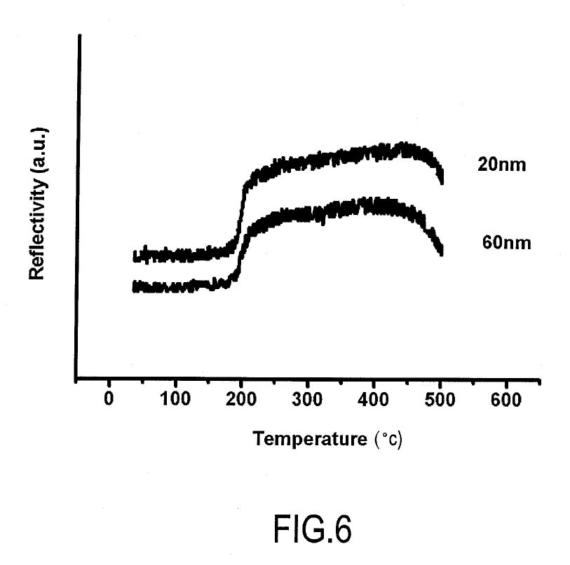

With reference to FIG. 6, reflectivities of a phase-change recording film of AgInSbTe and SiO₂ with two different thicknesses (20 nm and 60 nm) at different temperatures are shown. Both two phase-change recording films (20 nm and 60 nm) of AgInSbTe and SiO₂ have significant changes of reflectivity and similar slopes at about 200° C. Accordingly, the phase-change recording film in accordance with the present invention has a stable crystallization rate no matter the thickness of the phase-change recording film is. Therefore, manufacturing processes for manufacturing the phase-change recording film in accordance with the present invention do not require to be precisely controlled unduly and reduce costs.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A phase-change recording film being composed of
10 to 50 atomic percent of a phase-change material containing Te or Sb; and
50 to 90 atomic percent of a dielectric material.

2. The phase-change recording film as claimed in claim 1, wherein the phase-change material containing Te or Sb is GeSbTe, AgInSbTe, SbTe, GaInSbTe or GeTe.

3. The phase-change recording film as claimed in claim 2, wherein the dielectric material is Ta₂O₅, Si₃N₄, ZnS, SiO₂ or a mixture thereof.

4. The phase-change recording film as claimed in claim 1, wherein the dielectric material is Ta₂O₅, Si₃N₄, ZnS, SiO₂ or a mixture thereof.

5. A target for producing the phase-change recording film as claimed in claim 1 being composed of
a substrate being made of a dielectric material and having a surface; and
at least one sheet being made of phase-change material containing Te or Sb and attached to the surface of the substrate.

6. The target as claimed in claim 5, wherein the phase-change material containing Te or Sb is GeSbTe, AgInSbTe, SbTe, GaInSbTe or GeTe.

7. The target as claimed in claim 6, wherein the dielectric material is Ta₂O₅, Si₃N₄, ZnS, SiO₂ or a mixture thereof.

8. The target as claimed in claim 5, wherein the dielectric material is Ta₂O,, Si₃N₄, ZnS, SiO₂ or a mixture thereof.

9. A composite target for producing the phase-change recording film as claimed in claim 1 being composed of
10 to 50 atomic percent of a phase-change material containing Te or Sb; and
50 to 90 atomic percent of a dielectric material.

10. The composite target as claimed in claim 9, wherein the phase-change material containing Te or Sb is GeSbTe, AgInSbTe, SbTe, GaInSbTe or GeTe.

11. The composite target as claimed in claim 10, wherein the dielectric material is Ta₂O₅, Si₃N₄, ZnS, SiO₂ or a mixture thereof.

12. The composite target as claimed in claim 9, wherein the dielectric material is Ta₂O₅, Si₃N₄, ZnS, SiO₂ or a mixture thereof.

13. A co-sputtering process for producing the phase-change recording film as claimed in claim 1 using a target made of a dielectric material and a target made of a phase-change material containing Te or Sb to co-sputter.

14. The co-sputtering process as claimed in claim 13, wherein the phase-change material containing Te or Sb is GeSbTe, AgInSbTe, SbTe, GaInSbTe or GeTe.

15. The co-sputtering process as claimed in claim 14, wherein the dielectric material is Ta₂O₅, Si₃N₄, ZnS, SiO₂ or a mixture thereof

16. The co-sputtering process as claimed in claim 13, wherein the dielectric material is Ta₂O,, Si₃N₄, ZnS, SiO₂ or a mixture thereof.
